(19) United States
(12) Patent Application Publication
(10) Pub. No.: US 2025/0311455 A1
(43) Pub. Date: Oct. 2, 2025

(54) SEMICONDUCTOR PACKAGE AND METHOD OF FABRICATING THE SAME

(71) Applicant: Samsung Electronics Co., Ltd., Suwon-si (KR)

(72) Inventors: Tsuyoshi Ogawa, Yokohama (JP); Koji Hamaguchi, Yokohama (JP); Kazutaka Honda, Yokohama (JP); Kosuke Hareyama, Yokohama (JP)

(21) Appl. No.: 19/013,031

(22) Filed: Jan. 8, 2025

(30) Foreign Application Priority Data
Apr. 2, 2024 (JP) 2024-059329
Jun. 24, 2024 (KR) 10-2024-0081991

(51) Int. Cl. H10F 39/18; H10F 39/00

(52) U.S. Cl. CPC H10F 39/18; H10F 39/804; H10F 39/8063; H10F 39/811; H10F 39/014

(57) ABSTRACT

Provided are a semiconductor package having high contact reliability of contact terminals and excellent heat-radiating ability, and a method of fabricating the semiconductor package. The semiconductor package includes a semiconductor chip in which an electrode is formed on a first surface of a chip substrate, a transparent substrate including a wiring layer, a pillar electrode connected to the electrode through the wiring layer, and an encapsulation resin layer covering the wiring layer, wherein the pillar electrode is connected to the wiring layer through a first conducting portion, includes a first end portion and a second end portion, wherein the encapsulation resin layer covers side surfaces of the pillar electrode and the first conducting portion exposing the second end portion, and a chip second conducting portion is formed on a second surface of the chip substrate and a pillar second conducting portion is on an exposed surface of the second end portion.

### CROSS-REFERENCE TO RELATED APPLICATION

This U.S. non-provisional application is based on and claims priority under 35 U.S.C. § 119 to Japanese Patent Application No. 2024-059329, filed on Apr. 2, 2024, in the Japan Patent Office, and to Korean Patent Application No. 10-2024-0081991, filed on Jun. 24, 2024, in the Korean Intellectual Property Office, the disclosures of which are incorporated by reference herein in their entireties.

### BACKGROUND

The inventive concept relates to a semiconductor package, and more particularly, to a semiconductor package provided with a contact terminal and a method of fabricating the semiconductor package.

Recently, to cope with downsizing and high integration of semiconductor chips, flip-chip mounting using semiconductor packages as chip scale packages (CSP) have been widely adopted. Having a size almost identical to a size of a semiconductor chip, a CSP has a small package size and excellent productivity in a wafer level process, but has poor reliability of solder connection in package mounting. The poor reliability of solder connection in package mounting results from a great difference between a linear expansion coefficient (to 3 ppm/° C.) of silicon included in a chip substrate of a semiconductor chip, i.e., a mother body of the CSP, and a linear expansion coefficient (15 ppm/° C. to 20 ppm/° C.) of a mounting substrate, e.g., a mother board on which the CSP is mounted, which causes increase in stress applied to a solder (a contact terminal) and a periphery thereof due to thermal expansion difference with respect to temperature changes such as a temperature cycle. In addition, in these mounting packages, due to few radiation paths for heat generated from the device and high thermal resistances, when the device is operated, a junction temperature (TJ) may increase, and properties of the device may be degraded. In fan-out packages in the related art, it is required to increase a size of a solder ball, i.e., a contact terminal, up to a size much greater than a thickness of the device, a pitch itself between pins of the contact terminal may increase, and thus a size of the package itself may increase. There has been development on a device configured to solve such problems and increase the number of terminals.

### SUMMARY

The inventive concept provides a semiconductor package having high contact reliability in contact terminals and extra heat-radiating ability, and a method of fabricating the semiconductor package.

Technical goals to be achieved by the inventive concept are not limited thereto, and other technical goals may be clearly understood to those skilled in the art from the following written descriptions.

According to an aspect of the inventive concept, there is provided a semiconductor package including a semiconductor chip in which an electrode is formed on a first surface of a chip substrate to which light is incident, a pillar electrode being in electrical contact with the electrode through the wiring layer, and an encapsulation resin layer covering the wiring layer of the transparent substrate at a periphery of the semiconductor chip, wherein the pillar electrode is in contact with the wiring layer through the first conducting portion and includes a first end portion being in contact with the first conducting portion, a second end portion facing the first end portion, and a side surface connecting the first end portion to the second end portion, wherein the encapsulation resin layer covers the side surface of the pillar electrode and a side surface of the first conducting portion such that the second end portion of the pillar electrode is exposed, wherein a chip second conducting portion is formed on a second surface facing the first surface of the chip substrate and a pillar second conducting portion is formed on an exposed surface of the second end portion of the pillar electrode.

According to another aspect of the inventive concept, there is provided a semiconductor package including a transparent substrate in which a wiring layer is provided on a bottom surface thereof, a semiconductor chip which is under the transparent substrate and in which a microlens and an electrode are formed on a first surface of a chip substrate to which light is incident through the transparent substrate, a pillar electrode adjacent to the semiconductor chip and connected to the electrode through the wiring layer, an encapsulation resin layer covering the wiring layer of the transparent substrate and the pillar electrode at a periphery of the semiconductor chip, and a pillar contact terminal on a bottom surface of the pillar electrode and a chip contact terminal on a second surface of the first surface of the chip substrate, wherein the pillar electrode is connected to the wiring layer through a first conducting portion.

Furthermore, in another aspect of the inventive concept, there is provided a semiconductor package including a transparent substrate in which a wiring layer is provided on a bottom surface thereof, an image sensor which is under the transparent substrate in a form of a semiconductor chip, the image sensor having a first surface which faces the transparent substrate and on which a microlens is formed, a pillar electrode adjacent to the image sensor and under the transparent substrate, and an encapsulation resin layer covering a periphery of the image sensor and the pillar electrode on the bottom surface of the transparent substrate and in which a light-blocking portion blocking light of a reception wave of the image sensor, wherein the pillar electrode is connected to an electrode on the first surface of the image sensor through the wiring layer, wherein a first conducting portion having elasticity lower than elasticity of the pillar electrode is between the pillar electrode and the wiring layer.

According to another aspect of the inventive concept, there is provided a method of fabricating a semiconductor package, the method comprising: forming a microlens and an electrode on a first surface of a semiconductor chip, forming a wiring layer on a first surface of a transparent substrate, forming a first conducting portion on the wiring layer, forming a pillar electrode on the first conducting portion, mounting the semiconductor chip in a flip-chip structure on the transparent substrate, forming an encapsulation resin layer covering a periphery of the semiconductor chip and the pillar electrode, and forming a pillar contact terminal on the pillar electrode and a chip contact terminal on the semiconductor chip, wherein, in the mounting of the semiconductor chip in the flip-chip structure, the first surface of the semiconductor chip faces the first surface of the transparent substrate, the electrode is connected to the wiring layer, and in the forming of the pillar contact terminal and the chip contact terminal, the pillar contact terminal is formed on an exposed first surface of the pillar electrode and the chip contact terminal is formed on a second surface facing the first surface of the semiconductor chip.

According to a further aspect of the inventive concept, the method further includes: before the forming of the pillar contact terminal and the chip contact terminal, forming a pillar second conducting portion on the first surface of the pillar electrode and a chip second conducting portion on the second surface of the semiconductor chip, and in the forming of the pillar contact terminal and the chip contact terminal, the pillar contact terminal is formed on the pillar second conducting portion on the first surface of the pillar electrode and the chip contact terminal is formed on the chip second conducting portion on the second surface of the semiconductor chip.

### BRIEF DESCRIPTION OF THE DRAWINGS

Embodiments will be more clearly understood from the following detailed description taken in conjunction with the accompanying drawings in which:

FIG. 1 is a cross-sectional view of a semiconductor device in a state where a semiconductor package according to some embodiments is mounted on a mounting substrate;

FIG. 2 is a cross-sectional view illustrating the semiconductor package in the semiconductor package shown in FIG. 1;

FIGS. 3A to 3J are cross-sectional views each illustrating a method of fabricating a semiconductor package according to some embodiments, according to example methods;

FIG. 4 is a cross-sectional view illustrating an example semiconductor package according to some embodiments;

FIGS. 5A and 5B are cross-sectional views illustrating example semiconductor packages according to embodiments; and

FIG. 6 is a graph illustrating a result of performing simulation on lives of solders in some embodiments and a comparative example.

### DETAILED DESCRIPTION OF THE EMBODIMENTS

Hereinafter, embodiments will be described with reference to the accompanying drawings. In the following descriptions, same reference numerals indicate same components, and sizes of the components in the drawings may be exaggerated for clarity and convenience of explanation. Embodiments described below are only examples, and various modifications may be made based on the embodiments.

Hereinafter, the written expressions such as “above” or “on” may include a component above another component in a non-contact manner, as well as a component directly on another component in a contact manner. Likewise, the written expressions such as “under” or “below” may include a component under another component in a non-contact manner, as well as a component directly below another component in a contact manner.

Unless clearly indicated as a singular form, a singular form encompasses a plural form. Thus, the description of a single item that is provided in plural should be understood to be applicable to the remaining plurality of items unless context indicates otherwise.

In addition, when a portion is referred to as “includes”, “comprises”, or “has”, unless otherwise written, it does not indicate that other components are excluded but indicates that the portion may further include other components. When a component is described as “including” a particular element or group of elements, it is to be understood that the component is formed of only the element or the group of elements, or the element or group of elements may be combined with additional elements to form the component, unless the context indicates otherwise.

Orders will be clearly written with respect to processes included in the methods herein. Unless otherwise written, the processes may be performed in appropriate orders. The orders of the present methods are not necessarily limited to the written orders. Use of all examples or indicative terms are only used to describe the inventive concept, and unless defined by the claims, the scope of the inventive concept is not limited to the examples or indicative terms.

In addition, when ordinal numbers such as “first,” “second”, etc. are used in the following descriptions, unless specifically mentioned, the ordinal numbers are used only for convenience and are not used to define certain orders. It will be understood that, although the terms first, second, third, etc. may be used herein to describe various elements, components, conducting portions, end portions, surfaces, terminals, and processes, these elements, components, conducting portions, end portions, surfaces, terminals, and processes should not be limited by these terms. Unless the context indicates otherwise, these terms are only used to distinguish one element, component, conducting portions, end portions, surfaces, terminals, and processes from another one element, component, conducting portions, end portions, surfaces, terminals, and processes, for example as a naming convention.

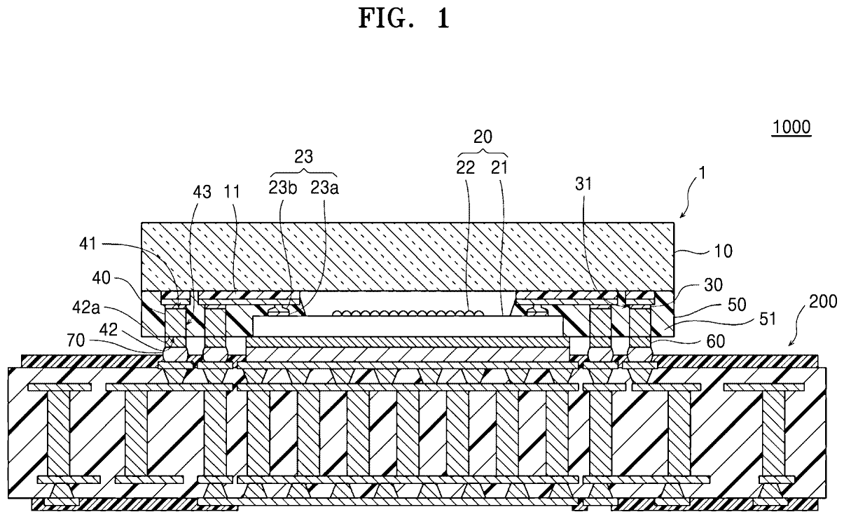

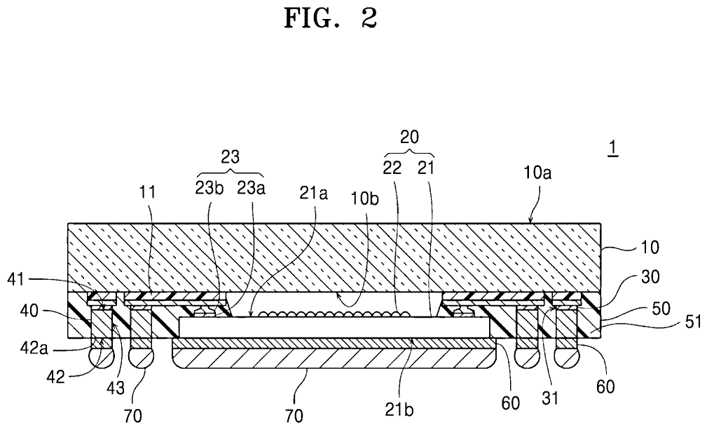

FIG. 1 is a cross-sectional view is a cross-sectional view illustrating a semiconductor device 1000 in a state where a semiconductor package 1 according to some embodiments is mounted on a mounting substrate 200, and FIG. 2 is a cross-sectional view illustrating a portion of the semiconductor package 1 in the semiconductor device 1000 illustrated in FIG. 1. The semiconductor device 1000 may include a semiconductor chip (i.e., a semiconductor device singulated from (e.g., cut from) a wafer).

Referring to FIGS. 1 and 2, the semiconductor package 1 of the embodiment may include a package of a fan-out structure in which a semiconductor chip 20 is constructed with a solid-state imaging device (e.g., a complementary metal oxide semiconductor (CMOS) image sensor) and which has wirings expanded to an area having a size greater than a size of the semiconductor chip 20, as illustrated in FIGS. 1 and 2.

As illustrated in FIG. 1, the semiconductor package 1 of the embodiment may include a transparent substrate 10, a semiconductor chip 20, a first conducting portion 30, a pillar-type electrode 40, and an encapsulation resin layer 50. The terms “pillar-type” and “pillar” are used interchangeably herein). As illustrated in FIG. 1, the semiconductor package 1 may be mounted on the mounting substrate 200 through a contact terminal 70. For example, the semiconductor device 1000 may have the semiconductor package 1 mounted on the mounting substrate 200.

The transparent substrate 10 may include transparent materials having light transmissivity, e.g., glass or a resin material such as polyimide. A plane size of the transparent substrate 10 may be not less than a plane size of a chip substrate 21 of the semiconductor chip 20. As illustrated in FIG. 2, the transparent substrate 10 may have a first surface 10a, i.e., an incident surface to which light is incident, and a second surface 10b on an opposite side of the transparent substrate, facing the first surface 10a. The transparent substrate 10 may be combined to the encapsulation resin layer 50 in a state where the second surface 10b of the transparent substrate 10 faces a first surface 21aof the chip substrate 21 of the semiconductor chip 20. In FIG. 2, the first surface 10a of the transparent substrate 10 may include a top surface of the transparent substrate 10, and the second surface 10b of the transparent substrate 10 may be a bottom surface of the transparent substrate 10.

A wiring layer 11 may be formed on the second surface 10b of the transparent substrate 10. The wiring layer 11 may electrically connect the semiconductor chip 20 and the pillar-type electrode 40. The wiring layer 11 may be formed by stacking a single layer or a plurality of layers of metal materials, such as copper (Cu) and gold (Au), through wiring forming methods such as a photolithography method. The wiring layer 11 may be formed, for example, by plating a copper (Cu) wire with gold (Au).

The semiconductor chip 20 may have a chip substrate 21 formed of silicon and the like. An integrated circuit (IC) pattern and the like may be formed on a first surface 21a of the chip substrate 21. In FIG. 2, the first surface 21a of the chip substrate 21 of the semiconductor chip 20 may include a top surface (an incident surface) of the chip substrate 21, and may also include an active surface. A second surface 21b of the chip substrate 21 of the semiconductor chip 20 may be a bottom surface of the chip substrate 21, and may also include an inactive surface. It should be understood that “top” and “bottom” designations depend on the orientation of the semiconductor chip 20. The first surface 21a, i.e., the active surface, is referred to as a front-side, and the second surface 21b, i.e., the inactive surface, is referred to as a back-side.

The semiconductor chip 20 may have a photodetecting region, in which a plurality of pixels configured to convert incident light into electrical signals are arranged in a column shape in lengthwise and breadthwise directions, and may be constructed as a CMOS image sensor including a microlens (or an on-chip lens) 22, a color filter, a photodiode, a pixel circuit, and the like. In FIGS. 1 and 2, the color filters, the photodiodes, the pixel circuit, and the like are not illustrated.

An electrode 23 may be formed on the first surface 21a of the semiconductor chip 20. The electrode 23 may be constructed by forming a stud bump 23b including Au and the like on the bonding pad 23a. The electrode 23 may be formed at a position at which the electrode 23 is conductible with the wiring layer 11 formed on the transparent substrate 10.

The first conducting portion 30 may be between the wiring layer 11 and the pillar-type electrode 40, and may electrically connect the wiring layer 11 and the pillar-type electrode 40. The first conducting portion 30 may include a conductive paste, e.g., a conductive adhesive including Cu particles, or a solder. The first conducting portion 30 may be formed through print forming methods, e.g., a screen-printing method or an inkjet-printing method.

Elasticity of the first conducting portion 30 may be less than elasticity of the pillar-type electrode 40. For example, a relationship between elasticity of the first conducting portion 30 and the pillar-type electrode 40 may fulfill a relationship of elasticity of the first conducting portion being less than elasticity of the pillar-type electrode. Elasticity may be determined by methods available to those in the art. In the semiconductor package 1 of the embodiment, stress applied to the contact terminal 70 due to a thermal expansion difference may be effectively reduced by forming the first conducting portion 30, which has elasticity less than the elasticity of the pillar-type electrode 40, the first conducting portion 30 being between the wiring layer 11 and the pillar-type electrode 40.

The pillar-type electrode 40 may be formed by being stacked on the first conducting portion 30. The pillar-type electrode 40 may include an electrode member having a first terminal 41 (or first end portion) being in contact with the first conducting portion 30, a second terminal 42 (or second end portion) opposite to the first terminal 41 in an axial direction and on which the contact terminal 70 and the like are formed, and a side surface 43 connecting the first terminal 41 to the second terminal 42. The pillar-type electrode 40 may include a metal pin (a copper pin), which includes copper as a main material, or a pillar-shaped member formed of copper plating formed through plating methods such as electrical plating or chemical plating. As a copper pin is used in the pillar-type electrode 40, it is only necessary to arrange a metal pin having a function as an electrode at a position at which the first conducting portion 30 is formed, and by doing so, the ease of assembly during fabrication may be improved. The encapsulation resin layer 50 may be formed by covering a side surface 31 of the first conducting portion 30 and the side surface 43 of the pillar-type electrode 40 at least at a periphery of the semiconductor chip 20. As illustrated in FIG. 2, the encapsulation resin layer 50 may be formed to cover the wiring layer 11 and expose the second surface 21b of the semiconductor chip 20 and the second end portion 42 of the pillar-type electrode 40. As used herein the term “covering” is intended to mean that an element is over or on or aside another element. The elements may be touching or not. Also an element need not cover an entire surface of an element to be considered “covering”. The term is intended to encompass one element covering all or any part of another element.

In the semiconductor package 1 of the embodiment, a position of an exposed surface 42a of the second terminal 42 and a position of the second surface 21b of the semiconductor chip 20 may be at a substantially same height in a thickness direction of the semiconductor package 1. Accordingly, when forming the second conducting portion 60 and the contact terminal 70, heights in the thickness direction of the semiconductor package 1 may be adjusted, and the ease of fabrication of the semiconductor package 1 may be improved. In addition, as the contact terminal 70 stacked on the pillar-type electrode 40 and the contact terminal 70 stacked on the second surface 21b of the semiconductor chip 20 are substantially at a same position in a height direction, the semiconductor package 1 may be more easily mounted.

The encapsulation resin layer 50 may include a resin having insulating ability, for example, an epoxy resin applicable as a potting resin. The encapsulation resin layer 50 may include a non-conductive filler, e.g., an inorganic filler having a spherical or plane shape, including silica and the like. A content of the non-conductive filler in the encapsulation resin layer 50 may be adjusted such that the reliability of solder contact of the semiconductor package 1 is optimized. By adjusting the content of the filler, it is possible to adjust a linear expansion coefficient or elasticity of the encapsulation resin layer 50. Accordingly, the semiconductor package 1 of the embodiment includes the encapsulation resin layer 50, of which the content of the filler has been adjusted such that the reliability of solder contact is optimized, to implement a package having excellent reliability of solder contact.

The encapsulation resin layer 50 may have a linear expansion coefficient not less than a linear expansion coefficient of the chip substrate 21 of the semiconductor chip 20. The linear expansion coefficient of the encapsulation resin layer 50 may be 5 ppm/° C. to 15 ppm/° C., for example, may have a value greater than the linear expansion coefficient (up to 3 ppm/° C.) of the chip substrate 21 of the semiconductor chip 20 and close to a linear expansion coefficient (15 ppm/° C. to 20 ppm/° C.) of the mounting substrate 200. Linear expansion coefficients may be determined by those skilled in the art. Being formed between the semiconductor chip 20 and the mounting substrate 200, the encapsulation resin layer 50 may function as a stress relief layer significantly reducing stress applied to the contact terminal 70 that may occur due to a thermal change between the semiconductor chip 20 and the mounting substrate 200.

When the semiconductor chip 20 is constructed as an image sensor, the encapsulation resin layer 50 may construct a light-blocking portion 51 blocking light of reception wavelength of the image sensor. For example, the encapsulation resin layer 50 may include a light-blocking material such as carbon or a filler to obtain light-blocking ability, and thus an entirety of the encapsulation resin layer 50 may function as the light-blocking portion 51. In addition, the encapsulation resin layer 50 may include, as the light-blocking portion 51, a film or a layer by which the light-blocking ability may be obtained by covering a portion or the entirety of the encapsulation resin layer 50. In the semiconductor package 1 in which the image sensor is mounted, by forming the light-blocking portion 51 in the encapsulation resin layer 50, an adverse effect to the image sensor due to stray light such as reflected light or scattered light may be reduced.

The second conducting portion 60 may be formed on the exposed surface 42a of the second end portion 42 of the pillar-type electrode 40 and the second surface 21b of the semiconductor chip 20. The second conducting portion 60 may include a conductive material, e.g., a material including copper, such as copper paste or copper plating, as a main component. The second conducting portion 60 may be formed through a screen printing method or an inkjet printing method, in a state in which a mask is formed in an area except a position at which the second conducting portion 60 is to be formed.

The second conducting portion 60 may function as a conductive layer that electrically connects the pillar-type electrode 40 and the contact terminal 70. The second conducting portion 60 may be formed with an area not less than an area of the exposed surface 42a of the second end portion 42 of the pillar-type electrode 40. Accordingly, in the semiconductor package 1, when the contact terminal 70 is formed at the second conducting portion 60, a size of the contact terminal 70 may be adjusted according to the size of the area of the second conducting portion 60.

In addition, the second conducting portion 60 may be formed on the second surface 21b of the semiconductor chip 20 and function as a chip pad of the semiconductor chip 20, solely or with the contact terminal 70. Accordingly, the semiconductor package 1 may radiate heat, which is generated from the semiconductor chip 20, to the mounting substrate 200 with high efficiency. In addition, being formed on the second surface 21b of the semiconductor chip 20, the second conducting portion 60 may also exhibit a shield effect against electrical noise from the mounting substrate 200. In addition, an effect of reducing stress on the pillar-type electrode 40 arranged around the semiconductor chip 20 may be obtained by using the second conducting portion 60. Being formed on an entire portion of the second surface 21b of the semiconductor chip 20, the second conducting portion 60 may effectively exhibit the aforementioned effects. In some embodiments, the second conducting portion 60 may also be formed in a portion of the second surface 21b of the semiconductor chip 20.

The contact terminal 70 may be formed on the exposed surface 42a of the second end portion 42 of the pillar-type electrode 40 or on the second conducting portion 60 formed on the second surface 21b of the semiconductor chip 20. The contact terminal 70 may include conductive materials such as a solder. In addition, in the configuration illustrated in FIG. 2, although the contact terminals 70 are formed in a manner of being stacked on the second conducting portion 60 formed on the pillar-type electrode 40 and the second conducting portion 60 formed on the second surface 21b of the semiconductor chip 20, the contact terminals 70 may be not formed on any one or both of the second conducting portions 60.

Regarding the semiconductor package 1 of an embodiment, as stress on the contact terminal 70 due to thermal changes during package mounting is reduced, a package with high contact reliability of the contact terminal 70 and excellent heat-radiating performance may be implemented. In detail, as the first conducting portion 30 having low elasticity is formed between the wiring layer 11 and the pillar-type electrode 40, the stress applied to the contact terminal 70 due to the thermal change during package mounting may be reduced, and accordingly, contact reliability of the contact terminal 70 may be improved. In addition, being formed to cover side surfaces of the first conducting portion 30 and the pillar-type electrode 40, the encapsulation resin layer 50 may function as the stress relief layer reducing the stress applied to the contact terminal 70 due to the thermal change. In addition, the second conducting portion 60 formed on a back-side of the semiconductor chip 20 may radiate the heat, which is generated from the semiconductor chip 20, to the mounting substrate 200 with high efficiency, and also may exhibit the shield effect against the electrical noise from the mounting substrate 200.

For reference, in an existing semiconductor package structure (see No. JP2019-040893A), a through electrode is used in place of a solder ball, and a bi-layer structure including a glass adhesive resin and a molding resin is used, and a manufacturing process thereof is complicated. In addition, due to insufficient solutions regarding stress-relieving ability for a solder or heat- radiating ability of a semiconductor chip, the semiconductor package structure needs to be improved. In addition, due to a difference between positions in a thickness direction of a contact terminal formed on through electrode arranged around the semiconductor chip and a contact terminal arranged below the semiconductor chip, it may be difficult to mount the package. However, all of the abovementioned problems may be solved in the semiconductor package 1 of example embodiments. For example, the semiconductor package 1 of the example embodiments may implement a semiconductor package in which the solder contact reliability is improved by reducing solder stress due to the thermal change during the package mounting and which has excellent heat-radiating ability.

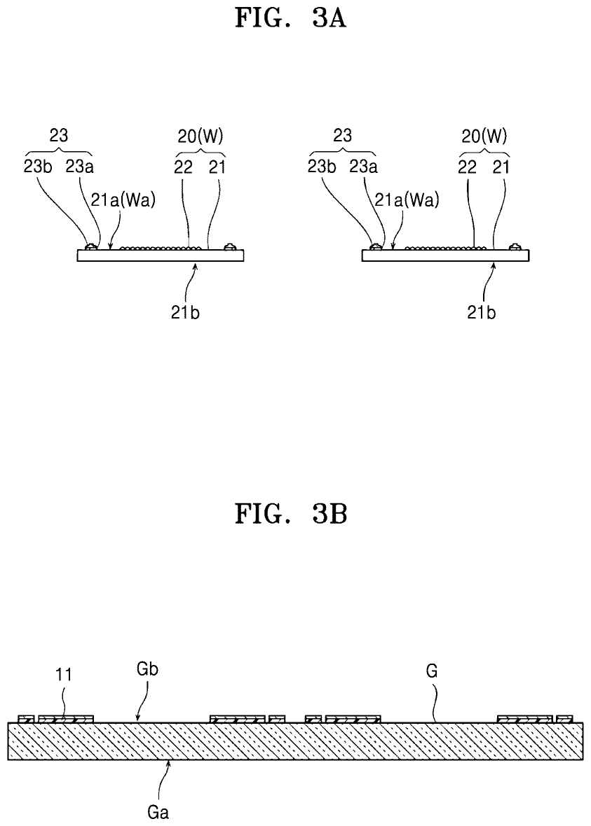

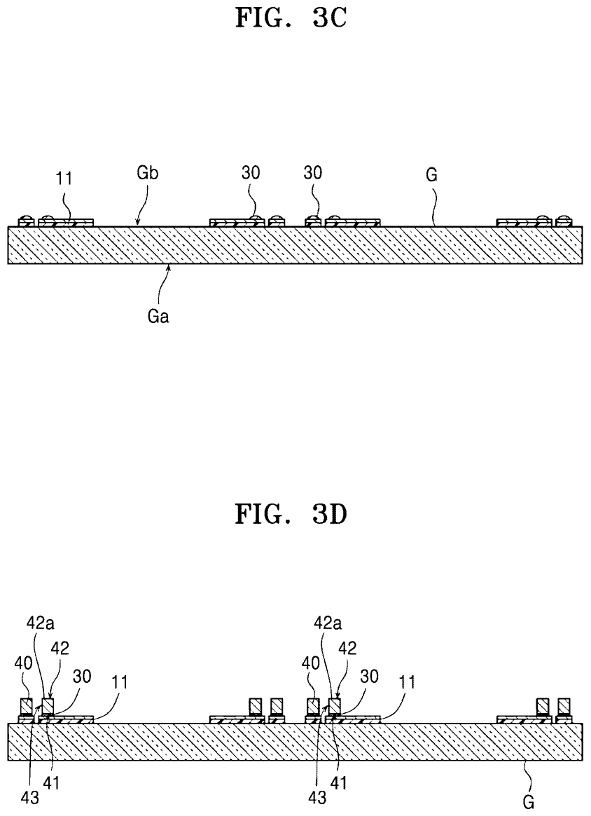

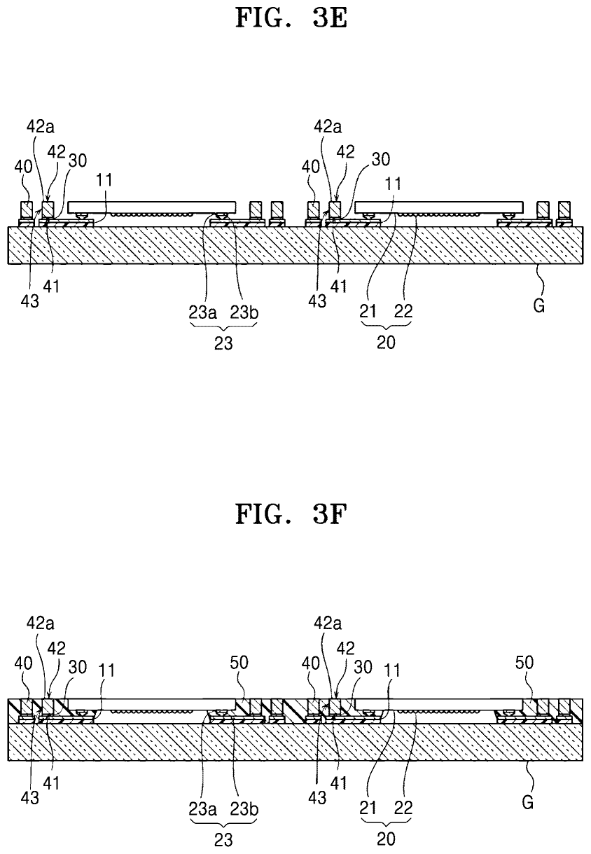

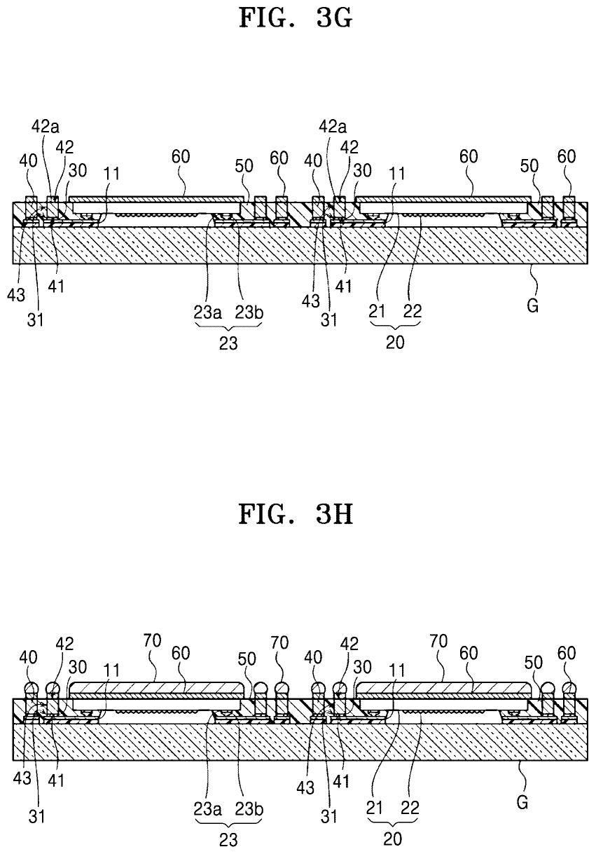

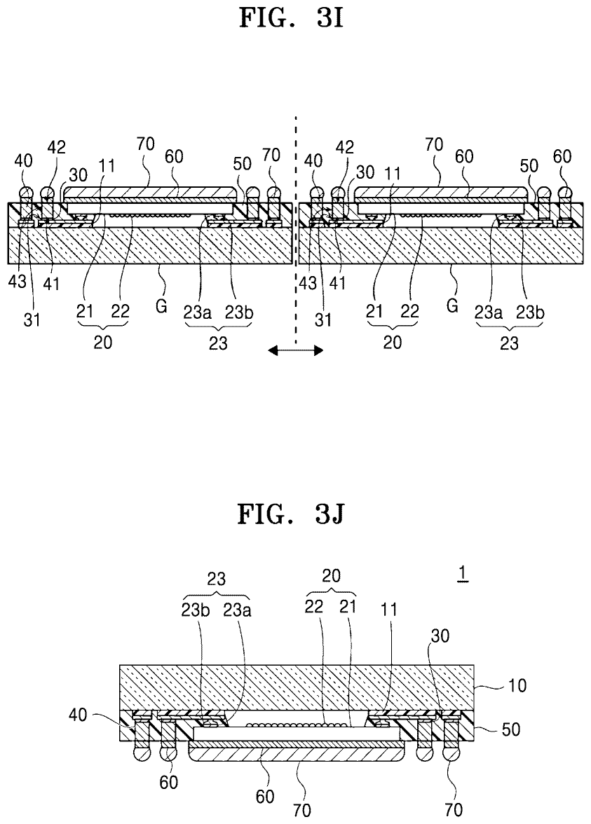

FIG. 3A to 3J are cross-sectional views each illustrating a method of fabricating the semiconductor package 1 according to some embodiments, according to example methods. Descriptions provided herein with reference to FIGS. 1 or 2 will be briefly given or omitted, as they should be understood to be as provided herein.

The method of fabricating the semiconductor package, according to some embodiments, may include, for example, methods of fabricating the semiconductor package 1 illustrated in FIG. 2, and may include first to ninth processes described herein. In addition, FIGS. 3A to 3J illustrate configurations in the processes (the first process to ninth process) included in the methods of fabricating the semiconductor packages of some embodiments.

Referring to FIG. 3A, in the first process, a process of forming the electrode 23 on a first surface Wa of a semiconductor wafer W, i.e., the chip substrate 21 of the semiconductor chips 20, is performed, as illustrated in FIG. 3A. The electrode 23 may be formed by forming the stud bump 23b including Au and the like on the bonding pad 23a. The electrode 23 may be formed on the chip substrate 21 of each of the semiconductor chips 20 of the semiconductor wafer W. In addition, a microlens 22 may be formed on the chip substrate 21 of each of the semiconductor chips 20 of the semiconductor wafer W. For reference, FIG. 3A illustrates, for convenience, the semiconductor chips 20 separated from the semiconductor wafer W, and the first surface Wa of the semiconductor wafer W may correspond to the first surface 21a of the semiconductor chip 20.

Referring to FIG. 3B, in the second process, a process of forming the wiring layer 11 on a second surface Gb facing a first surface Ga of the glass substrate G, i.e., the transparent substrate 10, is performed, as illustrated in FIG. 3B. The wiring layer 11 may be formed by forming a Cu wiring and then plating the surface of the Cu wiring with Au.

Referring to FIG. 3C, in the third process, a process of forming the first conducting portions 30 by coating a conductive paste to be stacked on the wiring layer 11 formed on the glass substrate G is performed, as illustrated in FIG. 3C. The first conducting portions 30 may be formed on the wiring layer 11 corresponding to the positions at which the pillar-type electrodes 40 are formed. A process of forming the first conducting portions 30 may be implemented through the screen printing method or the inkjet printing method, in a state in which a mask is formed in an area except positions at which the first conducting portions 30 are to be formed.

Referring to FIG. 3D, in the fourth process, a process of arranging the pillar-type electrodes 40 on the first conducting portions 30 is performed, as illustrated in FIG. 3D. A process of arranging the pillar-type electrode 40, which is similar to a ball mounting method, may be implemented by a process of forming a mask in an area other than the first conducting portion 30 such that the first conducting portion 30 is exposed, a process of transporting a plurality of copper pins, i.e., the pillar-type electrodes 40, on a mask, bringing the copper pins in contact with an opening of the mask by arranging the copper pins to respective of the first conducting portions 30, and a process of removing the mask and drying, sintering, and curing the first conducting portion 30. In the pillar-type electrode 40, an end portion being in contact with the first conducting portion 30 may include the first end portion 41 (or first terminal).

Referring to FIG. 3E, in the fifth process, a process of mounting the semiconductor chip 20, on which the electrode 23 is formed in the first process, in a flip-chip structure on the transparent substrate 10 is performed, as illustrated in FIG. 3E. The semiconductor chip 20 may be in electrical contact with the wiring layer 11 of the transparent substrate 10 through the electrode 23.

Referring to FIG. 3F, in the sixth process, a process of forming the encapsulation resin layer 50 is performed, as illustrated in FIG. 3F. To form the encapsulation resin layer 50, a resin including a non-conductive filler in an epoxy resin and the like is coated, and a grinding process is performed on the encapsulation resin layer 50 to expose the exposed surface 42a of the second end portion 42 (or second terminal) of the pillar-type electrode 40. In grinding processing, back grinding may be performed on the second surface 21b of the semiconductor chip 20 to a thickness of a certain chip size, and back grinding may also be performed from a surface of the encapsulation resin layer 50 to expose the second end portion 42 of the pillar-type electrode 40. Accordingly, the encapsulation resin layer 50 may be formed to cover the side surfaces 31 and 43 of the first conducting portion 30 and the pillar-type electrode 40, and the wiring layer 11, in a state where the second end portion 42 of the pillar-type electrode 40 is exposed.

Referring to FIG. 3G, in the seventh process, a process of forming the second conducting portions 60 on the exposed surface 42a of the second end portion 42 of the pillar-type electrode 40 and the second surface 21b of the semiconductor chip 20 is performed, as illustrated in FIG. 3G. The process of forming the second conducting portion 60 may be implemented through the screen printing method or the inkjet printing method, in a state in which a mask is formed in a region except a position at which the second conducting portion 60 is formed.

Referring to FIG. 3H, in the eighth process, a process of forming the contact terminal 70 on the second conducting portion 60 formed on the pillar-type electrode 40 and the semiconductor chip 20 is performed, as illustrated in FIG. 3H. Forming of the contact terminal 70 on the second end portion 42 of the pillar-type electrode 40 or the second surface 21b of the semiconductor chip 20 may be implemented through ball mounting method, screen printing method, and the like. In the eighth process, in terms of the ease of mounting, height positions of contact surfaces of the contact terminals 70 with respect to the mounting substrate 200 may be formed at a substantially same height in the thickness direction of the semiconductor package 1.

Referring to FIGS. 3I and 3J, in the ninth process, a process of singulation on the semiconductor package 1 by cutting certain spots of a glass substrate G is performed, as illustrated in FIG. 3I. The semiconductor package 1 illustrated in FIG. 3J may be fabricated through the aforementioned processes.

In some embodiments, the method of fabricating the semiconductor package according to the embodiment may further include other treatment processes (e.g., a cleaning process) other than the first process to the ninth process. In addition, in the method of fabricating the semiconductor package of the embodiment, orders of performing the processes may be appropriately modified as long as configurations and functions of the semiconductor package do not deviate from essential points of the inventive concept. Furthermore, the semiconductor package 1 may not include the contact terminal 70 on the second conducting portion 60 of the second end portion 42 of the pillar-type electrode 40 or the second surface 21b of the semiconductor chip 20. In this case, in the method of fabricating the semiconductor package of the embodiment, the eighth process illustrated in FIG. 3H may be omitted.

The semiconductor package 1 of some embodiments may be appropriately modified like in modified examples described hereinafter. In addition, in descriptions of the modified examples, differences from the semiconductor package 1 in FIG. 2 will be mainly described, same or relative reference numerals will be given to components having equivalent functions, and detailed descriptions will be omitted. Furthermore, configurations, members, and usage may be identical between the examples. In addition, in a range of not deviating from the essential points of the inventive concept, each modified example may be performed by appropriately selecting configurations among the configurations shown in each of the modified examples and combining the selected configurations with other forms.

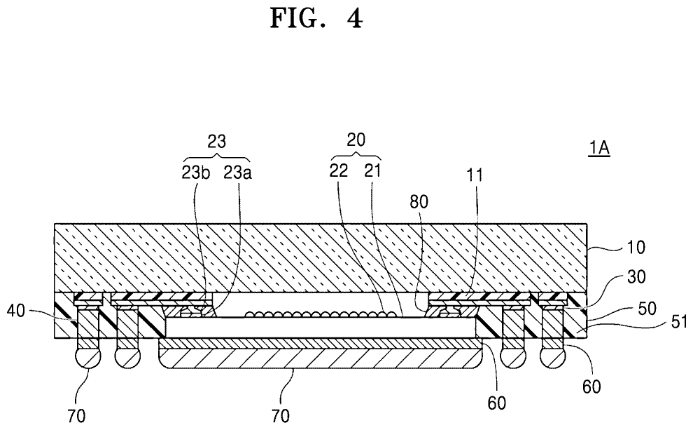

FIG. 4 is a cross-sectional view illustrating a shape of a semiconductor package 1A according to some embodiments. Descriptions provided herein with reference to FIGS. 1 to 3J will be briefly given or omitted.

Referring to FIG. 4, the semiconductor package 1A of the embodiment may be different from other types of packages in that at least a portion of the encapsulation resin layer 50 between the transparent substrate 10 and the semiconductor chip 20 is formed as an underfill layer 80.

The encapsulation resin layer 50 may be formed to cover a periphery of the semiconductor chip 20 after the semiconductor chip 20 is chip-mounted on the transparent substrate 10, and it may be difficult to insert the encapsulation resin layer 50 to a surface of the semiconductor chip 20. Therefore, in the semiconductor package 1A of the embodiment, encapsulation may be easily achieved by first forming an underfill material including an epoxy resin and the like as main materials for at least a portion of an area between the transparent substrate 10 and the semiconductor chip 20 and then forming the encapsulation resin layer 50. The underfill layer 80 may include an insulator resin having insulating ability.

As a part of the method of fabricating the semiconductor package 1A of the embodiment, the process of forming the underfill layer 80 may be performed between the fifth process illustrated in FIG. 3E and the sixth process illustrated in FIG. 3F. For example, in the fifth process, after mounting the semiconductor chip 20 on the transparent substrate 10, the underfill material may be inserted between the transparent substrate 10 and the semiconductor chip 20, and by doing so, the underfill layer 80 may be formed. Next, the sixth process is performed to form the encapsulation resin layer 50.

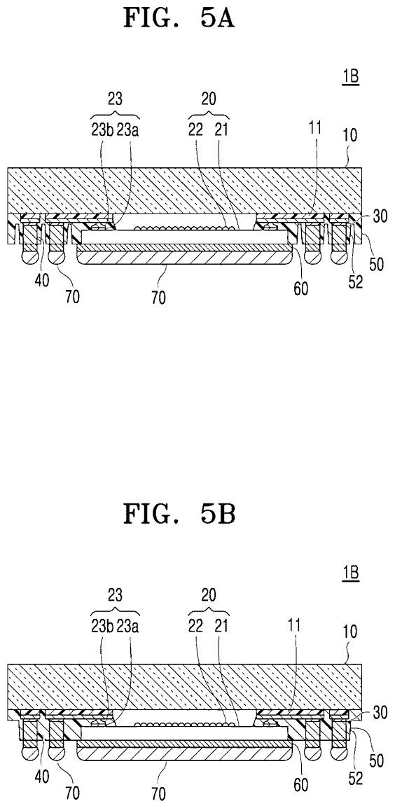

FIGS. 5A and 5B are cross-sectional views illustrating shapes of a semiconductor package 1B according to some embodiments. Descriptions provided herein with reference to FIGS. 1 to 4 will be briefly given or omitted.

Referring to FIGS. 5A and 5B, the semiconductor package 1B of the embodiments may be different from other types of packages in that a groove portion 52 is formed in the encapsulation resin layer 50. According to example embodiments, the encapsulation resin layer 50 includes a groove portion 52 formed in a portion of a periphery of the encapsulation resin layer 50.

The encapsulation resin layer 50 may have the groove portion 52. An effect of significantly reducing deformation (bending and the like) of the semiconductor package due to stress or thermal change during solder contact on the encapsulation resin layer 50 may be given by the groove portion 52.

As illustrated in FIG. 5A, the groove portion 52 may be formed between the pillar-type electrodes 40 adjacent to each other in a direction (a lateral direction in FIGS. 5A and 5B) crossing a thickness direction of the semiconductor package 1B. In addition, as illustrated in FIG. 5B, the groove portion 52 may be formed in a shape in which a portion of the periphery of the semiconductor package 1B is removed. Regarding the groove portion 52 shown in FIGS. 5A and 5B, the encapsulation resin layer 50 may be formed in advance into shapes illustrated in FIGS. 5A and 5B, or alternatively, may be formed through a shape processing to remove a portion of the shape illustrated in FIG. 2.

In addition, the groove portion 52 may be at least formed at a position at which the stress applied to the encapsulation resin layer 50 may be relieved. Accordingly, when the groove portion 52 has a shape exhibiting a stress-relieving effect, a shape or a position of the groove portion 52 may be not limited to the shapes or positions of formation illustrated in FIG. 5A or 5B.

As a part of the method of fabricating the semiconductor package 1B of the embodiment, a process of forming the groove portion 52 may be performed in an appropriate process after the sixth process illustrated in FIG. 3F. For example, after forming the encapsulation resin layer 50 in the sixth process, in an appropriate process, the groove portion 52 may be formed by removing a portion of the encapsulation resin layer 50. In addition, in the sixth process, the encapsulation resin layer 50 may be formed in a shape in which the groove portion 52 is formed in advance, and in this case, the aforementioned removing process may be unnecessary.

As described herein, the semiconductor package 1, 1A, or 1B according to some embodiments may include the semiconductor chip 20, in which the electrode 23 is formed on the first surface 21a that is the surface to which light from the chip substrate 21 is incident, the transparent substrate 10 having the wiring layer 11, the pillar-type electrode 40 being in electrical contact with the electrode 23 through the wiring layer 11, and the encapsulation resin layer 50 formed at a side of the wiring layer 11 of the transparent substrate 10 at the periphery of the semiconductor chip 20. The pillar-type electrode 40 may be in contact with the wiring layer 11 through the first conducting portion 30, and may include the first end portion 41 being in contact with the first conducting portion 30, the second end portion 42 facing the first end portion 41, and the side surface 43 connecting the first end portion 41 to the second end portion 42. The encapsulation resin layer 50 may be formed to cover the side surface 43 of the pillar-type electrode 40 and the side surface 31 of the first conducting portion 30, such that the second end portion 42 of the pillar-type electrode 40 is exposed. The second conducting portions 60 may be formed on the second surface 21b facing the first surface 21a of the chip substrate 21 and on the exposed surface 42a of the second end portion 42 of the pillar-type electrode 40.

The semiconductor package 1 of some embodiments includes the first conducting portion 30, which is between the wiring layer 11 and the pillar-type electrode 40, and the encapsulation resin layer 50 formed to cover the side surface 31 of the first conducting portion 30 and the side surface 43 of the pillar-type electrode 40, and therefore, the solder stress due to the thermal change when the semiconductor package 1 is mounted on the mounting substrate 200 may be significantly reduced. In addition, by preparing the second conducting portions 60 on the exposed surface 42a of the second end portion 42 of the pillar-type electrode 40 and the second surface 21b of the semiconductor chip 20, the stress applied to the contact terminal 70 formed on the pillar-type electrode 40 may be more efficiently reduced. In addition, as the second conducting portion 60 formed on the second surface 21b of the semiconductor chip 20 may function as the chip pad, the heat generated from the semiconductor chip 20 may be radiated to the mounting substrate 200 with high efficiency, and the shield effect against the electrical noise from the mounting substrate 200 may be exhibited. Accordingly, the soldering connection reliability, the heat-radiating ability in the package mounting, and electrical shielding performance of the semiconductor package 1 of the embodiment may be dramatically improved.

Advantageous effects of the semiconductor package of the embodiment will be described by using embodiments and comparison examples. However, the inventive concept is not limited to the following embodiments.

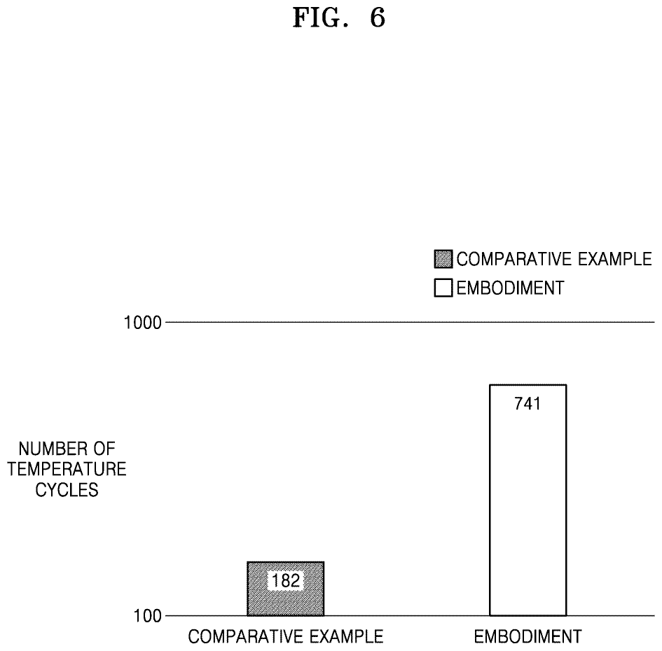

FIG. 6 is a graph illustrating a result of performing simulation on lives of solders in example embodiments and comparative examples, and in the following evaluation examination, the reliability in solder contact of the semiconductor package of the example embodiments was evaluated based on the result of performing the simulation on lives of solders.

Referring to FIG. 6, in the evaluation test, Marc2023 (manufactured by MSC Software Co., Ltd.) was used as structural analysis software. Simulation on the lives of the solders may be performed by, for example, methods written in the related document (“Prediction on Thermal Fatigue life of a Lead-free Solder Junction”, Technique Introductions of Technical Review, 2013-12, No. 49, Ima Tetsuya, Yamaha Motor Co. Ltd.).

The following conditions will be set for simulation of the evaluation test. A copy of the semiconductor package 1 illustrated in FIG. 2 will be used as a model in the embodiment, and a copy of a semiconductor package of a general fan-out package will be used as a model in the comparison example. In consideration of symmetry, a ¼ model will be used for each of the models. Here, the ¼ model, which is modeling for simulation, indicates performing the simulation only on ¼ of the semiconductor package under condition of symmetry in left-right and up-down, not on an entire portion of the semiconductor package. An element class is set as a hexahedron having twenty nodes. Symmetrical constraint and temperature-time dependence for all of the nodes are set as boundary conditions. In addition, the temperature-time dependence is set as a condition of an initial temperature of 175° C., i.e., a curing temperature of the stress relief layer, the model is cooled down to room temperature (25° C.), and a temperature cycle test condition from −55° C. to 125° C. is performed ten cycles. As properties of materials, materials of the substrate, the semiconductor chip, the transparent substrate, the wiring layer, the first conductive layer, and a dam are defined to have temperature-independent elastic properties, and a potting resin is set to have viscoelasticity. In addition, the solder is set to have plasticity.

In the evaluation test, to calculate the lives of the solders, a time-plasticity deformation history of a node having a maximum value of total plasticity deformation is obtained from a result of the simulation, plastic deformation at a tenth cycle is extracted from the history, and the extracted plasticity deformation is used as an amplitude of plastic deformation. The number of life cycles of the solders will be calculated from the amplitude of the plastic deformation that has been obtained and the Coffin-Manson law. It is known that the number of fatigue life cycles of a solder is calculated according to the Law of Coffin-Manson.

FIG. 6 illustrates the result of evaluation. The result of evaluation shown in FIG. 6 represents a result of prediction on the number of temperature cycles in the embodiment and the comparative example. For reference, a greater number of temperature cycles indicates that the solder has a long life and high reliability in solder contact.

As illustrated in FIG. 6, the number of temperature cycles in the comparative example is one hundred and eighty-two. On the contrary, the number of temperature cycles in the embodiment is seven hundred and forty-one. Based on the result, it is known that the life of the solder may be prolonged about four times by adopting the semiconductor package of example embodiments.

As described herein, the semiconductor package 1 of the embodiment includes a first conducting portion 30 between the wiring layer 11 of the transparent substrate 10 and the pillar-type electrode 40 being in electrical contact with the wiring layer 11, the pillar-type electrode 40, the encapsulation resin layer 50 formed at a side of the wiring layer 11 of the transparent substrate 10 at the periphery of the semiconductor chip 20 to cover the side surface 31 of the first conducting portion 30, and the second conducting portion 60 formed on the second end portion 42 of the pillar-type electrode 40, and thus, the reliability in solder contact may be improved by reducing solder stress due to temperature changes when the package is mounted.

Although the inventive concept has been described with reference to the embodiments illustrated in the drawings, the descriptions are merely examples, and those skilled in the art would understand that various modifications and other embodiments may be made based on the inventive concept.

While the inventive concept has been particularly shown and described with reference to embodiments thereof, it will be understood that various changes in form and details may be made therein without departing from the spirit and scope of the following claims.

1. A semiconductor package comprising:
a semiconductor chip in which an electrode is formed on a first surface of a chip substrate to which light is incident;
a transparent substrate on which a wiring layer is provided;
a pillar electrode being in electrical contact with the electrode through the wiring layer; and
an encapsulation resin layer covering the wiring layer of the transparent substrate at a periphery of the semiconductor chip, wherein
the pillar electrode is in contact with the wiring layer through a first conducting portion,
the pillar electrode comprises: a first end portion being in contact with the first conducting portion; a second end portion facing the first end portion at an opposite end of the pillar electrode; and a side surface connecting the first end portion to the second end portion,
the encapsulation resin layer covers the side surface of the pillar electrode and a side surface of the first conducting portion exposing the second end portion of the pillar electrode,
a chip second conducting portion on a second surface of the chip substrate facing the first surface of the chip substrate,
and a pillar second conducting portion on an exposed surface of the second end portion of the pillar electrode.

2. The semiconductor package of claim 1, wherein elasticity of the first conducting portion is less than elasticity of the pillar electrode.

3. The semiconductor package of claim 1, wherein
at least a portion of the encapsulation resin layer between the semiconductor chip and the transparent substrate, is formed as an underfill layer.

4. The semiconductor package of claim 1, wherein
the pillar second conducting portion has an area not less than an area of the exposed surface on the exposed surface of the second end portion of the pillar electrode, and the chip second conducting portion covers an entire second surface of the chip substrate.

5. The semiconductor package of claim 1, wherein the pillar electrode is a metal pin.

6. The semiconductor package of claim 1, wherein the encapsulation resin layer comprises a non-conductive filler.

7. The semiconductor package of claim 1, wherein
a linear expansion coefficient of the encapsulation resin layer is not less than a linear expansion coefficient of the chip substrate of the semiconductor chip.

8. The semiconductor package of claim 1, wherein the first conducting portion comprises a conductive paste or a solder.

9. The semiconductor package of claim 1, wherein the chip second conducting portion and the pillar second conducting portion comprise a material including copper as a main component.

10. The semiconductor package of claim 1, wherein,
the encapsulation resin layer includes a groove portion formed in a portion of a periphery of the encapsulation resin layer.

11. The semiconductor package of claim 1, wherein
a pillar contact terminal is formed on the exposed surface of the second end portion of the pillar electrode or on the pillar second conducting portion.

12. The semiconductor package of claim 1, wherein the semiconductor chip comprises an image sensor.

13. The semiconductor package of claim 12, wherein
the encapsulation resin layer comprises a light-blocking portion blocking light of a reception wavelength of the image sensor.

14. A semiconductor package comprising:
a transparent substrate provided with a wiring layer on a bottom surface of the transparent substrate;
a semiconductor chip under the transparent substrate, in which semiconductor chip a microlens and an electrode are formed on a first surface of a chip substrate to which light is incident through the transparent substrate;
a pillar electrode adjacent to the semiconductor chip and connected to the electrode through the wiring layer;
an encapsulation resin layer covering the wiring layer of the transparent substrate and the pillar electrode, at a periphery of the semiconductor chip; and
a pillar contact terminal on a bottom surface of the pillar electrode, and a chip contact terminal on a second surface facing the first surface of the chip substrate, wherein the pillar electrode is connected to the wiring layer through a first conducting portion.

15. The semiconductor package of claim 14, wherein elasticity of the first conducting portion is less than elasticity of the pillar electrode.

16. The semiconductor package of claim 14, wherein
a chip second conducting portion is on the second surface of the chip substrate and a pillar second conducting portion is on the bottom surface of the pillar electrode,
the pillar contact terminal is on a bottom surface of the pillar second conducting portion,
the pillar second conducting portion is on the bottom surface of the pillar electrode with an area not less than an area of the bottom surface of the pillar electrode,
the chip contact terminal is on a bottom surface of the chip second conducting portion, and
the chip second conducting portion is on the second surface of the chip substrate to cover an entire portion of the second surface of the chip substrate.

17. The semiconductor package of claim 14, wherein
the encapsulation resin layer covers side surfaces of the pillar electrode and the first conducting portion, and
a linear expansion coefficient of the encapsulation resin layer is not less than a linear expansion coefficient of the chip substrate of the semiconductor chip.

18. The semiconductor package of claim 14, wherein
the semiconductor chip comprises an image sensor, and
the encapsulation resin layer comprises a light-blocking portion blocking light of a reception wavelength of the image sensor.

19. A semiconductor package comprising:
a transparent substrate provided with a wiring layer on a bottom surface thereof;
an image sensor under the transparent substrate in a form of a semiconductor chip, the image sensor having a first surface which faces the transparent substrate and on which a microlens is formed;
a pillar electrode under the transparent substrate and adjacent to the image sensor; and
an encapsulation resin layer covering a periphery of the image sensor and the pillar electrode, on a bottom surface of the transparent substrate, and comprising a light-blocking portion blocking light of a reception wavelength of the image sensor, wherein
the pillar electrode is connected to an electrode on the first surface of the image sensor through the wiring layer, and
a first conducting portion having elasticity lower than elasticity of the pillar electrode is between the pillar electrode and the wiring layer.

20. The semiconductor package of claim 19, wherein
a pillar second conducting portion is on a second surface facing the first surface of the image sensor and on a bottom surface of the pillar electrode,
a pillar contact terminal is on a bottom surface of the pillar second conducting portion, and
the pillar second conducting portion has an area not less than an area of the bottom surface of the pillar electrode at the bottom surface of the pillar electrode, and a chip second conducting portion covers an entire portion of the second surface of the image sensor on the second surface of the image sensor.

21-22. (canceled)
